(19) United States
(12) Patent Application Publication
(10) Pub. No.: US 2014/0168893 A1
(43) Pub. Date: Jun. 19, 2014

(54) HEAT DISSIPATION APPARATUS WITH ANTENNA AND ELETRONIC SYSTEM APPLIED THE SAME

(71) Applicant: ASUSTEK COMPUTER INC., Taipei (TW)

(72) Inventors: Chia-Ching NIU, TAIPEI (TW); Cheng-Yu WANG, TAIPEI (TW)

(73) Assignee: ASUSTEK COMPUTER INC., TAIPEI (TW)

(21) Appl. No.: 13/787,838

(22) Filed: Mar. 7, 2013

(30) Foreign Application Priority Data
Dec. 13, 2012 (TW) 101147214

(51) Int. Cl. H05K 7/20

(52) U.S. Cl. CPC H05K 7/20136
USPC 361/692

(57) ABSTRACT

A heat dissipation apparatus with an antenna is provided. The heat dissipation apparatus includes a housing, a heat-insulation structure, a fan and an antenna. The heat-insulation structure is disposed on the housing and the heat-insulation structure has a plurality of heat dissipation holes. The fan is disposed in the housing and an air exhaust channel is formed between the fan and the heat-insulation structure. The antenna is disposed in the air exhaust channel.

### RELATED APPLICATIONS

This application claims priority to Taiwan Application Serial Number 101147214, filed Dec. 13, 2012, which is herein incorporated by reference.

### BACKGROUND OF THE INVENTION

1. Field of the invention

The invention relates to a heat dissipation apparatus and, more particularly, to a heat dissipation apparatus with an antenna.

2. Description of the Related Art

Recently, the metal housing has become the new favorite for consumer electronics products. Metal housings are wildly used at smart phones, notebook computers, tablet personal computers (tablet PC) and so on to improve texture and uniqueness of the product. However, for consumer electronic products with the communication function, metal housings have a shielding effect on the antenna, and thus some additional designs needs to be added on the metal housing to solve this problem.

In addition, in order to meet the demands on heat dissipation, the metal housing often needs to have heat dissipation holes to dissipate heat through the heat dissipation holes. However, due to the good thermal conductivity of the metal housing, the hot air usually transfers the heat to the metal housing through the heat dissipation holes, and the temperature of the metal housing increases.

### BRIEF SUMMARY OF THE INVENTION

A heat dissipation apparatus with an antenna comprises a housing, a heat-insulation structure, a fan and an antenna. The heat-insulation structure is disposed on the housing, and the heat-insulation structure has a plurality of heat dissipation holes. The fan is disposed in the housing, and an air exhaust channel is formed between the fan and the heat-insulation structure. The antenna is disposed in the air exhaust channel.

An electronic system is also provided which comprises a housing, a display panel, a heat-insulation structure, a fan and an antenna. The display panel is disposed in the housing. The heat-insulation structure is disposed on the housing, and the heat-insulation structure has a plurality of heat dissipation holes. The fan is disposed in the housing, and an air exhaust channel is formed between the fan and the heat-insulation structure. The antenna is disposed in the air exhaust channel.

As the antenna is below the heat-insulation structure, it does not need to embed other plastic materials at the housing, which is space saving. In addition, since the heat can be slow conducted to other regions of the housing via the heat-insulation structure, it can avoid the overall temperature of the housing increases.

### BRIEF DESCRIPTION OF THE DRAWINGS

FIG. 1 is a three-dimensional schematic diagram showing a heat dissipation apparatus with an antenna according to one embodiment of the disclosure;

FIG. 2 is a partial enlarged drawing showing the heat dissipation apparatus in FIG. 1;

FIG. 3 is a bottom view diagram showing an electronic system with the heat dissipation apparatus in one embodiment; and

FIG. 4 is a top view diagram showing the electronic system in FIG. 3.

### DETAILED DESCRIPTION OF THE EMBODIMENTS

These and other features, aspects, and advantages of the invention will become better understood with regard to the following description, appended claims, and accompanying drawings.

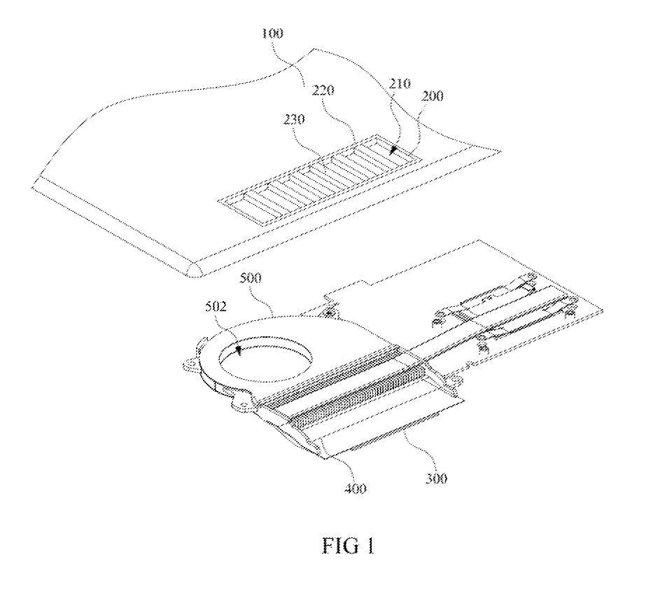

FIG. 1 is a three-dimensional schematic diagram showing a heat dissipation apparatus with an antenna in one embodiment. Please refer to FIG. 1. The heat dissipation apparatus mainly comprises a housing 100, a heat-insulation structure 200, an antenna 300, and a fan 500. The material of the housing 100 is conductor material.

The heat-insulating structure 200 is disposed on the housing 100, and the heat-insulation structure 200 has a plurality of heat dissipation holes 210. The heat-insulation structure 200 is made of non-conductor material, and the coefficient of the thermal conductivity of the housing 100 is greater than that of the heat-insulation structure 200. The fan 500 is disposed in the housing 100, and an air exhaust channel 504 is formed between the air outlet of the fan 500 and the heat-insulation structure 200.

As the heat-insulation structure 200 is made of non-conductor material, it does not have a shielding effect, and thus the antenna 300 near the heat-insulation structure 200 can transmit the electromagnetic wave outside the housing 100 via the heat-insulation structure 200. That is, the heat dissipation holes 210 of the heat-insulation structure 200 is not only used for cooling, but also can be used as a transmitting channel of the electromagnetic wave.

In addition, the heat-insulation structure 200 also may be made of the material with low coefficient of thermal conductivity to slow down the transfer of thermal energy, so as to avoid that the heat from the fan 500 transfers to other regions of the housing 100. Consequently, it can avoid over-temperature of the overall housing 100.

In the embodiment, the material of the housing 100 may be metal such as aluminum, aluminum alloy, magnesium alloy, or any combination thereof. In addition, the material of the heat-insulation structure 200 may be plastic such as Polycarbonate (PC), Phenylpropanolamine (PPA), Acrylonitrile Butadiene Styrene (ABS), Polypropylene (PP), polyethylene terephthalate (PET) Polybutylece terephthalate (PBT), or any combination thereof, which is not limited herein.

The heat-insulation structure 200 includes a frame body 220, and a plurality of ribs 230. The ribs 230 connect the opposite two edges of the frame body 220. In the embodiment, the ribs 230 may be parallel arranged, and any two adjacent ribs 230 together define a heat dissipation hole 210 therebetween.

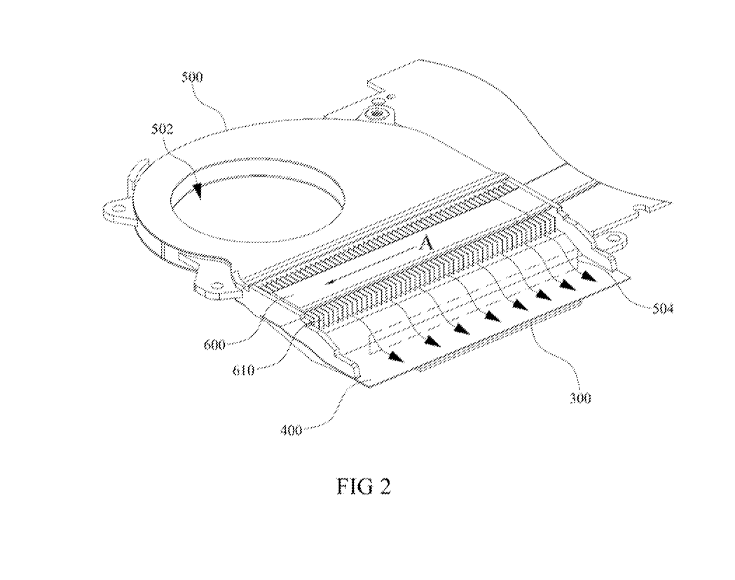

FIG. 2 is the partial enlarged drawing of the heat dissipation apparatus in FIG. 1. As shown in FIG. 2, the fan 500 has a fan blade region 502, the fan blade region 502 is used for mounting fan blades (not shown) to exhaust air out. The air exhausted by the fan 500 flows along the air exhaust channel 504, passes the antenna clearance region 400 and the heat dissipation holes 210 (see FIG. 1) to bring the heat outside the housing 100 (see FIG. 1).

In the embodiment, the heat dissipation apparatus may include a heat pipe 600 and a plurality of cooling fins 610. The end of the heat pipe 600 is disposed in the air exhaust channel 504. The cooling fins 610 contact the heat pipe 600 to transfer the heat from the heat pipe 600 to the cooling tins 610, and the air exhausted from the fan 500 absorbs the heat of the cooling fins 610, and the heat is dissipated via the air exhaust channel 504.

In the embodiment, the cooling fins 610 may be arranged along the longitudinal direction A of the heat pipe 600 intervally, and the air exhausted from the fan 500 flows through the gap between any two adjacent cooling fins 610, which is not limited.

In the embodiment, an antenna clearance region 400 is formed between the antenna 300 and the heat pipe 600 in the air exhaust channel, which can avoid the shielding effect.

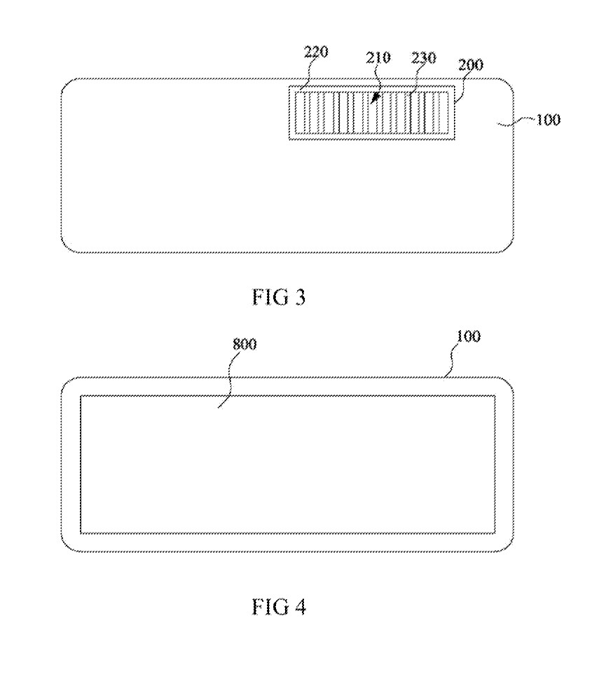

FIG. 3 is the bottom view diagram showing an electronic system with the heat dissipation apparatus in one embodiment. FIG. 4 is the top view diagram of the electronic system in FIG. 3. Please refer to FIG. 3 and FIG. 4, an electronic system mainly comprises the housing 100 and a display panel 800. The display panel 800 is disposed in the housing 100. The electronic system may include the heat-insulation structure 200, the antenna 300, the heat pipe 600, the cooling fins 610, and the fan 500 shown in FIG. 1. The structure, the positional relationship of these components, and the functions are described above, which is omitted herein for a concise purpose.

Although the invention has been described in considerable detail with reference to certain preferred embodiments thereof, the disclosure is not for limiting the scope. Persons having ordinary skill in the art may make various modifications and changes without departing from the scope. Therefore, the scope of the appended claims should not be limited to the description of the preferred embodiments described above.

What is claimed is:

1. A heat dissipation apparatus with an antenna, comprising:
a housing;
a heat-insulation structure disposed on the housing, wherein the heat-insulation structure includes a plurality of heat dissipation holes;
a fan disposed in the housing, wherein an air exhaust channel is formed between the fan and the heat-insulation structure; and
an antenna disposed in the air exhaust channel.

2. The heat dissipation apparatus with an antenna according to claim 1, wherein the air exhaust channel includes an antenna clearance region

3. The heat dissipation apparatus with an antenna according to claim 1, wherein the antenna is adjacent to the heat-insulation structure.

4. The heat dissipation apparatus with an antenna according to claim 1, wherein the material of the housing is metal.

5. The heat dissipation apparatus with an antenna according to claim 1, wherein the coefficient of the thermal conductivity of the heat-insulation structure is lower than the coefficient of the thermal conductivity of the housing.

6. The heat dissipation apparatus with an antenna according to claim 1, further comprising:
a heat pipe, wherein an end of the heat pipe is disposed in the air exhaust channel.

7. The heat dissipation apparatus with an antenna according to claim 6, further comprising:
a plurality of heat dissipation tins for contacting with the heat pipe.

8. An electronic system, comprising:
a housing;
a display panel disposed in the housing;
a heat-insulation structure disposed on the housing and having a plurality of heat dissipation holes;
a fan disposed in the housing, wherein an air exhaust channel is formed between the fan and the heat-insulation structure; and
an antenna disposed in the air exhaust channel.

9. The electronic system according to claim 8, further comprising:
a heat pipe, wherein an end of the heat pipe is disposed at the air exhaust channel.

10. The electronic system according to claim 9, further comprising:
a plurality of heat dissipation fins contacting the heat pipe.
